(19) United States
(12) Patent Application Publication
(10) Pub. No.: US 2020/0225066 A1
(43) Pub. Date: Jul. 16, 2020

(54) HIGH RESOLUTION CURRENT AND MAGNETIC FIELD SENSOR

(71) Applicant: Siemens Energy, Inc., Orlando, FL (US)

(72) Inventors: Evangelos V. Diatzikis, Chuluota, FL (US); Edward David Thompson, Casselberry, FL (US)

(21) Appl. No.: 16/631,000

(22) PCT Filed: Aug. 1, 2017
(86) PCT No.: PCT/US2017/044844

§ 371 Date: Jan. 14, 2020

(51) Int. Cl. G01D 5/48; G01D 5/04; G01D 5/26; G01R 15/24; G01R 33/032; G01B 9/02; G01R 5/00

(52) U.S. Cl. CPC G01D 5/485; G01D 5/04; G01D 5/266; G01R 5/00; G01R 15/248; G01R 33/0327; G01B 9/02; G01D 5/268

(57) ABSTRACT

A sensor for detecting an amount of current flowing in a wire wherein displacement of a sensing mirror is used in an interferometer to enable determination of the amount of current. The sensor includes a magnetostrictive element located within a magnetic field formed by the wire. The sensor also includes a position sensor that detects a size increase of the magnetostrictive element. In addition, the sensor includes an amplifying device that amplifies the size increase of the magnetostrictive element by a predetermined amplification factor to provide an amplified size increase. Further, the sensor includes a displacement device that displaces the sensing mirror by an amount corresponding to the amplified size increase.

### BACKGROUND

### 1. Technical Field

Aspects of the present invention relate to a sensor for detecting an amount of current flowing in a wire, and more particularly, to a sensor that includes a magnetostrictive element located within a magnetic field formed by the wire wherein a position sensor detects a size increase of the magnetostrictive element and the size increase is amplified by a predetermined amplification factor by an amplifying device to provide an amplified size increase wherein the sensing mirror is displaced by an amount corresponding to the amplified size increase.

### 2. Description of Related Art

It is desirable to make flux, voltage or current measurements on high voltage components or devices. But the presence of high voltages complicates the installation of sensors used to make the measurements. An example is the measurement of the current needed by generator neutral grounding devices utilized in electrical power generators for power plants. In this regard, the entire disclosure of US Patent Publication No. 2016/0266206A1 entitled “Generator Neutral Ground Monitoring Device Utilizing Direct Current Component Measurement and Analysis” is incorporated herein by reference in its entirety.

Fiber optic devices are often utilized in high voltage environments due to the dielectric properties of the materials used to make the devices. Such devices may include fiber optic sensors made of fibers coated with magnetostrictive films that can be used to measure magnetic fields, thus enabling determination of the current in a conductor. But such devices are suitable for higher current and voltage applications ranging from household power all the way up to high voltage transmission lines, and thus lack the resolution to measure small currents.

In particular, the generator neutral ground current is carried in a large conductor and can be as low as 30 mA in operation, but at a voltage that could potentially increase up to line voltage (sometimes over 20 kV) during a generator fault. Thus, a sensor for this application must be designed to withstand over 20 kV in order to enhance safety and reduce the likelihood of generator damage and down time for generator repairs. But providing suitable voltage isolation for the sensor is expensive and undesirably increases the size and weight of the sensor. Alternatively, measurement locations may be used that are in a lower voltage environment or generally safer area. Unfortunately, the current reading must be undesirably inferred or calculated based on various configuration parameters and thus is prone to measurement error.

### SUMMARY

Aspects of the present invention relate to a sensor for detecting an amount of current flowing in a wire wherein displacement of a sensing mirror is used in an interferometer to enable determination of the amount of current. The sensor includes a magnetostrictive element located within a magnetic field formed by the wire. The sensor also includes a position sensor that detects a size increase of the magnetostrictive element. In addition, the sensor includes an amplifying device that amplifies the size increase of the magnetostrictive element by a predetermined amplification factor to provide an amplified size increase. Further, the sensor includes a displacement device that displaces the sensing mirror by an amount corresponding to the amplified size increase.

In another embodiment, the sensor includes a magnetostrictive element located within the magnetic field, wherein the magnetostrictive element includes a first rack gear. The sensor also includes a second rack gear that includes the sensing mirror. In addition, the sensor includes a gear set that engages the first and second rack gears wherein a size increase of the magnetostrictive element causes linear movement of the first rack gear and wherein the first and second rack gears and the gear set amplify the size increase of the magnetostrictive element by a predetermined amplification factor to provide an amplified size increase. Further, the second rack and sensing mirror are displaced by an amount corresponding to the amplified size increase.

Those skilled in the art may apply the respective features of the present invention jointly or severally in any combination or sub-combination.

### BRIEF DESCRIPTION OF DRAWINGS

The exemplary embodiments of the invention are further described in the following detailed description in conjunction with the accompanying drawings, in which:

FIG. 1 depicts a fiber optic interferometer schematic in accordance with an aspect of the invention.

FIG. 2 shows a magnetic field generated by current flowing in a wire.

FIG. 3 depicts an embodiment of a current and magnetic field sensor in accordance with an aspect of the invention in a rest position.

FIG. 4 depicts the sensor shown in FIG. 3 in an actuated position.

FIG. 5 depicts an alternate embodiment of the sensor.

To facilitate understanding, identical reference numerals have been used, where possible, to designate identical elements that are common to the figures. The figures are not drawn to scale.

### DETAILED DESCRIPTION

Although various embodiments that incorporate the teachings of the present disclosure have been shown and described in detail herein, those skilled in the art can readily devise many other varied embodiments that still incorporate these teachings. The scope of the disclosure is not limited in its application to the exemplary embodiment details of construction and the arrangement of components set forth in the description or illustrated in the drawings. The disclosure encompasses other embodiments and of being practiced or of being carried out in various ways. Also, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items. Unless specified or limited otherwise, the terms “mounted,” “connected,” “supported,” and “coupled” and variations thereof are used broadly and encompass direct and indirect mountings, connections, supports, and couplings. Further, “connected” and “coupled” are not restricted to physical or mechanical connections or couplings.

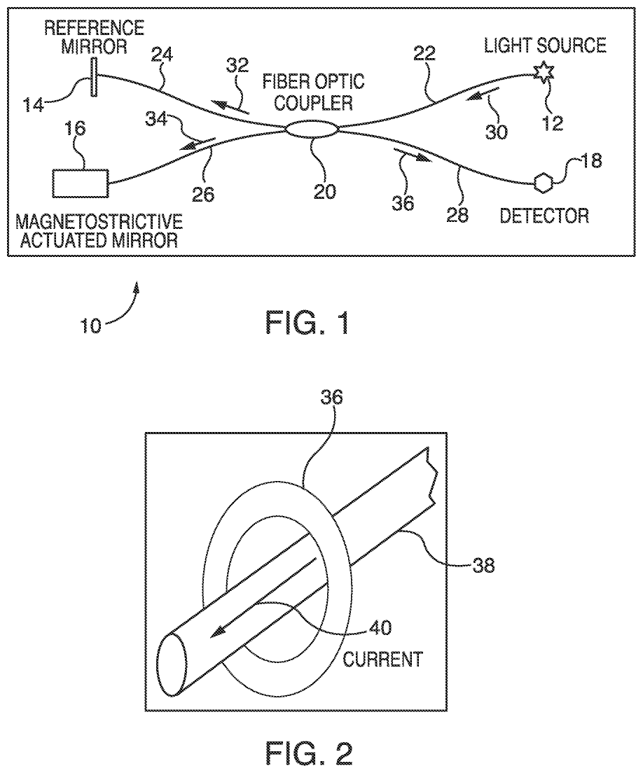

Referring to FIG. 1, a fiber optic interferometer schematic 10 in accordance with an aspect of the invention is shown. The interferometer 10 includes a light source 12, stationary reference mirror 14, moveable sensing mirror 16, detector 18 and fiber optic coupler 20. The interferometer further includes light source 22, reference 24, sensing 26 and detector 28 optical paths that connect the light source 12, reference mirror 24, sensing mirror 16 and detector 18, respectively, to the fiber optic coupler 20. The light source 22, reference 24, sensing 26 and detector 28 optical paths are each fabricated from optical fiber. Light 30 from the light source 12 travels along the light source optical path 22 and is split into first 32 and second 34 light beams by the fiber optic coupler 20 which may be a known beam splitter (i.e. a partially reflecting mirror). The first 32 and second 34 beams travel along the reference 24 and sensing 26 paths, respectively. An end of the reference path 24 terminates at the reference mirror 14 which is located a fixed distance from the fiber optic coupler 20. The sensing path 26 terminates at the sensing mirror 16 as will be described. The first 32 and second 34 beams traveling the reference 24 and sensing 26 paths are reflected by the reference 14 and sensing 16 mirrors, respectively, back to the fiber optic coupler 20. The first 32 and second 34 beams are then recombined into a single light beam 36 that travels along the detector optical path 28 and forms an interference pattern that is incident on the detector 18, which may be a photo detector. The interference pattern includes bright and dark fringes indicative of constructive and destructive interference, respectively, between the first 32 and second 34 beams. Any difference in the distance traveled by the second beam 32 relative to the first beam 32, due to a change in length of the sensing path 26 as a result of movement or displacement of the sensing mirror 16, creates a phase difference between the first 32 and second 34 beams.

As will be described, the sensing mirror 16 can be moved by a gear train that is actuated by a rod element made of a magnetostrictive material. Referring to FIG. 2, a magnetic field 36 generated by a current 40 flowing in a cable or wire 38 is shown. The wire 38 may be of the type used to carry a generator neutral ground current 40. Such wires 38 may be relatively large in size (i.e. approximately 1 inch diameter) compared to the relatively small current 40 (i.e. approximately 30-500 mA) carried by the wire 38 due to the electrical insulation needed for protecting against high voltages of 20 kV or more that may occur during a generator fault, for example. The strength of the magnetic field 36 depends on the amount of current 40 traveling through the wire 38 and the distance from the center of the wire 38.

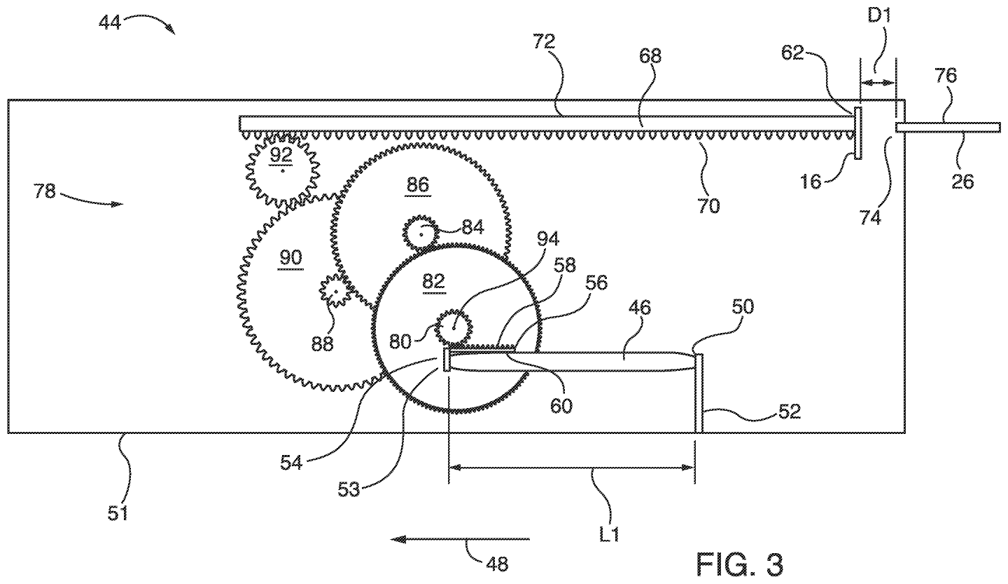

Referring to FIG. 3, an embodiment of a current and magnetic field sensor 44 in accordance with an aspect of the invention is shown. The sensor 44 includes a magnetostrictive rod 46 having a first length L1. A first, or stationary, end 50 of the magnetostrictive rod 46 is attached to a sensor frame by a bracket or first anchor 52. A second end 54 of the magnetostrictive rod 46 is not restrained and includes a second anchor 53 that attaches a first straight bar 56 the magnetostrictive rod 46. The first straight bar 56 includes a plurality of gear teeth 58 that form a first gear rack 60. The sensor 44 also includes the sensing mirror 16 (see FIG. 1) that is attached to an end 62 of a second straight bar 68 having a plurality of gear teeth 70 that form a second gear rack 72. The sensing mirror 16 is spaced apart from an optical fiber end 74 of an optical fiber 76, which forms a part of the sensing path 26, by a first distance D1 which is also part of the sensing path 26. The optical fiber end 74 is positioned so that light exits from the optical fiber end 74, travels to the sensing mirror 16, reflects from the sensing mirror 16, is received by the optical fiber end 74 and travels back along the sensing path 26 to the fiber optic coupler 20 as previously described. In FIG. 3, the sensor is shown in a rest position wherein the magnetostrictive rod 46 retains the first length L1 and the sensing mirror 16 is spaced apart from the optical fiber end 74 by the first distance D1.

Further, the sensor 44 includes a gear train 78 having a first gear 80. The first gear 80 may be adapted such that it that engages the first rack 60, a second gear 82 that engages a third gear 84, a fourth gear 86 that engages a fifth gear 88 and a sixth gear 90 that engages a seventh gear 92 that in turn engages the second rack 72. The first gear 80 is attached to the second gear 82, the third gear 84 is attached to the fourth gear 86 and the fifth gear 88 is attached to the sixth gear 90.

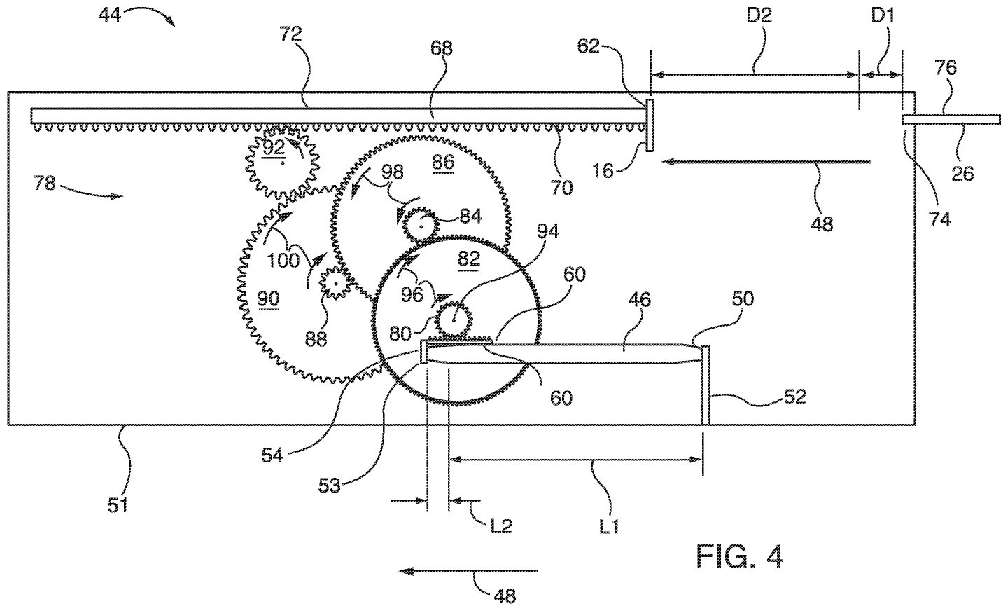

Referring to FIG. 4, the sensor 44 is shown in an actuated position. Linear movement of the first rack 60 in a first direction 48 oriented transverse to a rotation axis 94 of the first gear 80, i.e. horizontally from left to right in FIG. 4 for example, causes clockwise rotation 96 of the first 80 and second 82 gears. This, in turn, causes counterclockwise rotation 98 of the third 84 and fourth 86 gears, clockwise rotation 100 of the fifth 88 and sixth 90 gears, counterclockwise rotation 102 of the seventh gear 92 and linear movement of the second rack 72, and thus the sensing mirror 16, in the first direction 48 thereby displacing the sensing mirror 16.

In accordance with an aspect, the frame 51 may be positioned sufficiently close to the wire 38 such that the magnetostrictive rod 46 is located within the magnetic field 36 generated by the current 40 flowing in the wire 38. This causes a size (i.e. length) of the magnetostrictive rod 46 oriented in the first direction 48 to expand or increase by a second length L2, thus causing linear movement of the first rack 60 in the first direction 48. The linear movement, in turn, causes rotation of the gears 80, 82, 84, 86, 88, 90, 92 as previously described and ultimately movement of the second rack 72 and sensing mirror 16 in the first direction 48 such that the distance between the sensing mirror 16 and the optical fiber end 74 is increased by a second distance D2. As a result, a length of the sensing path 26 can be increased by the second distance D2, thus increasing the distance which the second beam 34 travels which, in turn, causes a phase difference between the first 32 and second 34 beams and the generation of light and dark fringe patterns on the detector 18 in a known manner. Thus, elongation of the magnetostrictive rod 46 (i.e. the change in position of the second end 54 due to the second length L2) as a result of the magnetic field 36 is detected by the gear train 78. The gear train 78 then causes displacement of the sensing mirror 16 away from the optical fiber end 74.

In an exemplary embodiment, due to the relatively small current 40 in the wire 38, an increase in the length of the magnetostrictive rod 46, by itself, may not be sufficient to enable measurement of current 40. Thus, a gear ratio for the gear train 78 can be selected such that the amount of lengthening of the magnetostrictive rod 46, i.e. the size increase of the magnetostrictive rod 46, is sufficiently magnified or amplified by the gear train 78 to provide an amplified size increase which in turn provides sufficient displacement of the sensing mirror 16 to enable determination of the amount of current 40 in the wire 38. In an embodiment, the gear train 78 is selected to provide an amplification factor of 212, which corresponds to the optical path difference between the reference 24 and sensing 26 paths. It is understood that the amplification factor of 212 is exemplary and that other amplification factors may be used depending on other factors including the type of magnetostrictive material used for the magnetostrictive rod 46 and desired resolution.

Typical magnetostrictive materials may include, for example and not limitation, TbFe₂, Tb_{0.5}Zn_{0.5}, TbₓDy₁₋ₓFe₂ (Terfenol-D), and Tb_{0.5}DyₓZn. Terfenol-D may be manufactured in rods with a diameter of approximately 10 mm up to 65 mm and 200 mm in length. It has been found by the inventors herein that Terfenol-D provides suitable resolution for the sensor 44. Table 1 shows selected properties for Terfenol-D and calculations for the sensor 44 when the magnetostrictive rod 46 is fabricated from Terfenol-D. It is understood that other magnetostrictive materials and configurations may be used for the magnetostrictive rod 46.

TABLE 1

| | Inputs | Units | Calculations | | |
|---|---|---|---|---|---|
| Micro- | 2000 | N/A | Rod Expansion | 200 | μm |
| strain | | | Length | | |
| Rod | 100 | mm | Mirror | 42520000 | nm |
| Length | | | Horizontal | | |
| | | | Displacement | | |
| Laser λ | 265 | nm | Fringe Shift | 320906 | fringes |
| Magnetic | 0.2 | T | Sensitivity | 6.23236E−07 | T/fringe |
| Field | | | (T = Tesla) | | |
| Radius | 0.02 | cm | | 0.0006 | mT/fringe |
| from wire | | | | | |
| | | | | 0.6 | μT/fringe |
| | | | Incremental | 0.001 | amps/ |
| | | | Detectable | | fringe |
| | | | Current | | |

Thus, the invention provides a sensor 44 having a resolution of approximately 0.001 amps (1 mA) per fringe with a sensitivity of approximately 0.6 μT per fringe.

As the sensing mirror 16 moves and the distance between the sensing mirror 16 and the optical fiber end 74 increases by the second distance D2, the number of cycles wherein a fringe change occurs (i.e. from a bright fringe to dark fringe, for example) on the detector 18 is counted in a known manner. The number of fringe changes is then multiplied by the calculated Incremental Detectable Current from Table 1 (i.e. 0.001 amps/fringe) to determine the current 40 in the wire 38.

It is understood that other mechanical or electromechanical systems may be instead of, or in combination with, the gear train 78 to detect lengthening of the magnetostrictive rod 46, magnify or amplify the amount of lengthening to provide an amplified size increase and cause displacement of the sensing mirror 16 by an amount corresponding to the amplified size increase. These include systems having a wedge arrangement, levers, belts, cams, a pantograph arrangement, screw mechanism, crank-slider mechanism and others.

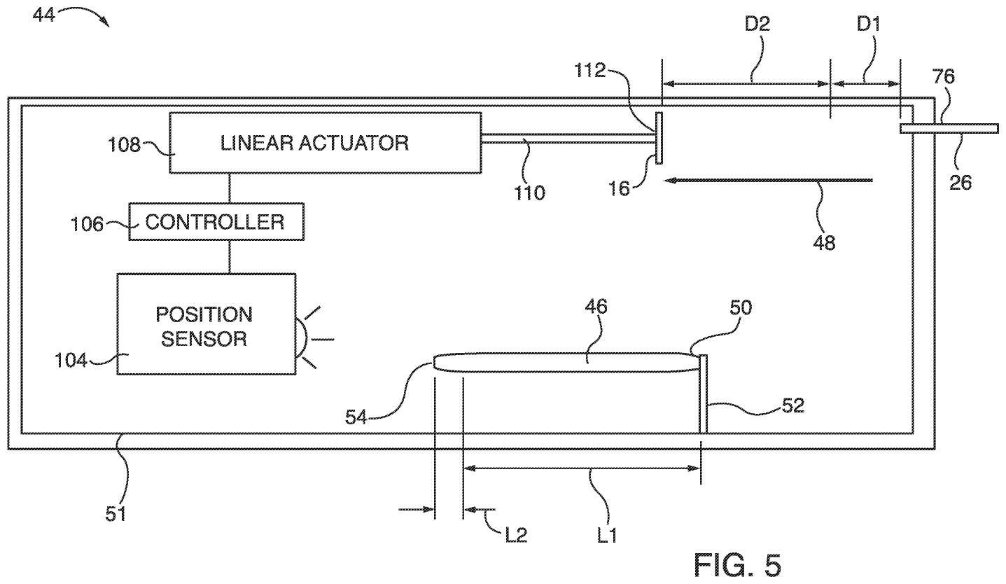

Referring to FIG. 5, an alternate embodiment of the sensor 44 is shown. In this embodiment, a noncontact displacement or linear position sensor 104 is used to detect a change in position of the second end 54 due to the second length L2. For example, the displacement sensor 104 may be a known capacitive, inductive or other type of noncontact position sensor. Alternatively, a resistive position sensor or a strain gauge arrangement may be used. The sensor 44 also includes a controller 106 for controlling a linear actuator 108 having a moveable output shaft 110. Alternatively, a servo motor may be used instead of the linear actuator 110. The sensing mirror 16 is located on an end 112 of the output shaft 110. In operation, information regarding a change in length of the magnetostrictive rod 46 (i.e. the second length L2) is received by the controller 106. The controller 106 then sends a command to the linear actuator 108 wherein the change in length is amplified based on a predetermined amplification factor that provides sufficient displacement of the output shaft 110 and thus the sensing mirror 16 (i.e. the second distance D2) to enable determination of the amount of current 40 in the wire 38 as previously described.

In another embodiment, the displacement sensor 104 and controller 106 may be located in a first housing and the linear actuator 108 may be located in a separate second housing. In this embodiment, the controller 106 may communicate with the linear actuator 108 using known wireless methods. This enables a reduction in size of the first frame to facilitate positioning of the first frame adjacent the wire 38, or to provide improved access to confined areas adjacent the wire 38, such that the magnetostrictive rod 46 is located within the magnetic field 36 generated by the current 40 flowing in the wire 38.

An aspect of the invention provides a high resolution sensor 44 that utilizes standard components such as single mode fibers, the fiber optic coupler 20, light source 12 and detector 18. Conventional fiber optic current sensors involve geometries, polarization maintain fibers, heterodyne and homodyne demodulation and other features that add undesirable cost and complexity to a sensor. In another aspect of the invention, a sensor 44 is provided that can be used in many applications where current or magnetic field measurements are difficult to make due to a high voltage environment or physical space limitations. In addition, the sensor 44 may be used in dangerous environments having explosive atmospheres and nuclear radiation. In another aspect of the invention, a sensor 44 is provided that measures relatively small currents or voltages in large conductors wherein the conductors may also be subjected to carrying large currents and voltages due to a generator fault, for example.

While particular embodiments of the present disclosure have been illustrated and described, it would be obvious to those skilled in the art that various other changes and modifications can be made without departing from the spirit and scope of the disclosure. It is therefore intended to cover in the appended claims all such changes and modifications that are within the scope of this disclosure.

What is claimed is:

1. A sensor for detecting an amount of current flowing in a wire, wherein the current generates a magnetic field and wherein displacement of a sensing mirror is used in an interferometer to enable determination of the amount of current, comprising:
a magnetostrictive element located within the magnetic field generated by the current wherein the magnetic field causes a change in size in the magnetostrictive element;
a position sensor that detects a size increase of the magnetostrictive element due to the magnetic field;
an amplifying device that amplifies the size increase of the magnetostrictive element by a predetermined amplification factor to provide an amplified size increase; and
a displacement device that displaces the sensing mirror by an amount corresponding to the amplified size increase wherein displacement of the sensing mirror is indicative of the amount of current in the wire.

2. The sensor according to claim 1, wherein the size increase includes a lengthening of the magnetostrictive element.

3. The sensor according to claim 1, wherein a first end of the magnetostrictive element is stationary and a second end of the magnetostrictive element is unrestrained to enable the size increase.

4. The sensor according to claim 1, wherein the amplifying device includes a gear set.

5. The sensor according to claim 1, wherein displacement of the sensing mirror increases a sensing path length of the interferometer.

6. The sensor according to claim 5, wherein a number of fringe changes in a fringe pattern of the interferometer is counted as the sensing mirror moves.

7. The sensor according to claim 6, wherein the amount of current is calculated by multiplying the number of fringe changes by the number of amps per fringe.

8. The sensor according to claim 1, wherein the current is a generator neutral ground current.

9. A sensor for detecting an amount of current flowing in a wire, wherein the current generates a magnetic field and wherein displacement of a sensing mirror is used in an interferometer to enable determination of the amount of current, comprising:
a magnetostrictive element located within the magnetic field generated by the current wherein the magnetic field causes a change in size in the magnetostrictive element and wherein the magnetostrictive element includes a first rack gear;
a second rack gear that includes the sensing mirror; and
a gear set that engages the first and second rack gears wherein a size increase of the magnetostrictive element due to the magnetic field causes linear movement of the first rack gear wherein the first and second rack gears and the gear set amplify the size increase of the magnetostrictive element by a predetermined amplification factor to provide an amplified size increase that displaces the second rack and sensing mirror by an amount corresponding to the amplified size increase wherein displacement of the sensing mirror is indicative of the amount of current in the wire.

10. The sensor according to claim 9, wherein the size increase includes a lengthening of the magnetostrictive element.

11. The sensor according to claim 9, wherein a first end of the magnetostrictive element is stationary and a second end of the magnetostrictive element is unrestrained to enable the size increase.

12. The sensor according to claim 9, wherein the size increase occurs in a direction transverse to rotation axis of a gear in the gear set.

13. The sensor according to claim 9, wherein the amplification factor is 212.

14. The sensor according to claim 9, wherein displacement of the sensing mirror increases a sensing path length of the interferometer.

15. The sensor according to claim 14, wherein a number of fringe changes in a fringe pattern of the interferometer is counted as the sensing mirror moves.

16. The sensor according to claim 15, wherein the amount of current is calculated by multiplying the number of fringe changes by the number of amps per fringe.

17. The sensor according to claim 9, wherein the current is a generator neutral ground current.

18. The sensor according to claim 9, wherein the magnetostrictive element is fabricated from a material having the formula TbₓDy₁₋ₓFe₂.

19. A method for detecting an amount of current flowing in a wire, wherein the current generates a magnetic field and wherein displacement of a sensing mirror is used in an interferometer to enable determination of the amount of current, comprising:
providing a magnetostrictive element located within the magnetic field generated by the current wherein the magnetic field causes a change in size in the magnetostrictive element and wherein the magnetostrictive element includes a first rack gear;
providing a second rack gear that includes the sensing mirror; and
providing a gear set that engages the first and second rack gears wherein a size increase of the magnetostrictive element due to the magnetic field causes linear movement of the first rack gear;
amplifying the size increase of the magnetostrictive element by a predetermined amplification factor to provide an amplified size increase;
displacing the second rack and sensing mirror by an amount corresponding to the amplified size increase wherein displacement of the sensing mirror is indicative of the amount of current in the wire.

20. The method according to claim 19, wherein the size increase includes a lengthening of the magnetostrictive element.
